(19) United States
(12) Patent Application Publication
(10) Pub. No.: US 2019/0198424 A1
(43) Pub. Date: Jun. 27, 2019

(54) POWER MODULE WITH BUILT-IN POWER DEVICE AND DOUBLE-SIDED HEAT DISSIPATION AND MANUFACTURING METHOD THEREOF

(71) Applicant: RAYBEN TECHNOLOGIES (ZHUHAI) LIMITED, Zhuhai (CN)

(72) Inventors: Wai Kin Raymond Lam, Zhuhai (CN); Ho Wai Derek Leung, Zhuhai (CN); Aibing Chen, Zhuhai (CN); Weidong Gao, Zhuhai (CN)

(73) Assignee: RAYBEN TECHNOLOGIES (ZHUHAI) LIMITED, Zhuhai (CN)

(21) Appl. No.: 15/956,771

(22) Filed: Apr. 19, 2018

(30) Foreign Application Priority Data
Dec. 21, 2017 (CN) 201711391152.9

(51) Int. Cl. H01L 23/40; H01L 23/492

(52) U.S. Cl. CPC H01L 23/40; H01L 2224/34; H01L 2924/13055; H01L 23/492

(57) ABSTRACT

Disclosed is a power module with built-in power device and double-sided heat dissipation and a manufacturing method thereof. The power module includes a first base plate including a first organic insulating base material, a first electrical insulating heat dissipation body, a first metal layer, and a patterned second metal layer; a second base plate including a second organic insulating base material and a second electrical insulating heat dissipation body. A third metal layer thermally connected to a side of the second electrical insulating heat dissipation body is formed at the outer side of the second base plate. A fourth metal layer thermally connected to the second electrical insulating heat dissipation body is formed at another side of the second electrical insulating heat dissipation body. The fourth metal layer is formed with a concave power device accommodating space, and the power device is arranged in the accommodating space.

### CROSS REFERENCE TO RELATED APPLICATIONS

This application is based upon and claims priority to Chinese Patent Application No. 201711391152.9 filed on Dec. 21, 2017, the entire contents of which are incorporated herein by reference.

### TECHNICAL FIELD

The present invention relates to a power module and a manufacturing method thereof, particularly, to a power module with built-in power device and double-sided heat dissipation and manufacturing method thereof.

### BACKGROUND

Power electronic devices such as IGBT (insulated gate bipolar transistor), MOSFET (metal-oxide semiconductor field effect transistor), thyristor, GTO (gate turn-off thyristor), GTR (Giant Transistor), BJT (bipolar junction transistor), UJT (unijunction transistor) and the like are widely used in various electronic/electrical equipment. With the development of electronic/electrical products in the direction of light weight and miniaturization, higher requirements have been raised for various performances of power electronic devices, for example, IGBT chips are required to withstand higher currents, etc. However, the heat generated by the power device increases with the increase in current carried by the power device. If the heat generated by the power device is not timely dissipated, the operation of power device and other electronic devices in the product will be seriously affected. Therefore, miniaturized power modules with high heat dissipation capability have become the common goal pursued by the industry.

Chinese patent application CN201110222484.0 discloses a wire-bonding-free IGBT block including a substrate, a liner plate soldered to the substrate, a power semiconductor chip and a collector terminal soldered to the liner plate, and a wire-free electrode lead-out board; the wire-free electrode lead-out board is a composite busbar or a multilayer printed circuit board disposed on the power semiconductor chip for electrode interconnection and lead-out of the power semiconductor chip and providing current and heat dissipation path for the block; the electrodes of the power semiconductor chip are interconnected through connection terminals on the wire-free electrode lead-out board, and the connection medium is silver.

Chinese patent application CN201621294680.3 provides a power block with double-sided heat dissipation. The IGBT block is soldered between a first heat dissipation plate and a second heat dissipation plate. The second heat dissipation plate is arranged with a positive power terminal, a negative power terminal, and an AC power terminal connected to the IGBT block. The IGBT block, the positive power terminal, and the AC power terminal form a first current loop. The IGBT block, the negative power terminal, and the AC power terminal form a second current loop. The AC power terminal is located between the positive power terminal and the negative power terminal.

Chinese patent application CN201780000036.1 discloses an IGBT module including a heat dissipation substrate. A first ceramic heat dissipation body is embedded within the heat dissipation substrate. The surface of the heat dissipation substrate is provided with a first circuit layer. The first side of the IGBT chip is attached on the first circuit layer. The second side of the IGBT chip is provided with a thermally conductive metal plate. A side of the first circuit layer is provided with the first heat dissipation plate configured with the first through hole. The IGBT chip and the thermally conductive metal plate are located in the first through hole. A side of the heat dissipation plate away from the IGBT chip is provided with the second circuit layer. The second circuit layer is arranged at a side of the thermally conductive metal plate. A side of the second circuit layer away from the IGBT is provided with the second ceramic heat dissipation body and the second heat dissipation plate configured with the second through hole. The second ceramic heat dissipation body is located in the second through hole. The second heat dissipation plate is further provided with a third circuit layer. Organic insulating medium is filled between the first heat dissipation plate and the heat dissipation substrate, the first heat dissipation plate and the second heat dissipation plate.

The drawback of the technical solution disclosed in this patent application is that a hot-pressing step is required during the manufacturing process of the IGBT module. If the hot pressing process is not properly controlled, the pressure exerted in the hot pressing step may be directly transmitted to the IGBT chip, which is prone to cause damage to the IGBT chip, thereby resulting in a low yield of the IGBT module.

### SUMMARY

The first objective of the present invention is to provide a power module with good heat dissipation capability, that can effectively prevent the power device from being damaged due to the hot pressing pressure during the manufacturing process.

The second objective of the present invention is to provide a method for manufacturing a power module having a double-sided heat dissipation structure, and such method can effectively prevent the power device from being damaged due to the hot pressing pressure during the manufacturing process.

In order to achieve the first objective mentioned above, the first aspect of the present invention is to provide a power module with built-in power devices and double-sided heat dissipation including:

a first base plate, wherein the first base plate includes a first organic insulating base material and a first electrical insulating heat dissipation body embedded in the first organic insulating base material; a first metal layer thermally connected to a side of the first electrical insulating heat dissipation body is formed at an outer side of the first base plate; a second metal layer thermally connected to another side of the first electrical insulating heat dissipation body is formed at an inner side of the first base plate, and the second metal layer is patterned;

a second base plate, wherein the second base plate includes a second organic insulating base material and a second electrical insulating heat dissipation body embedded in the second organic insulating base material; the first electrical insulating heat dissipation body and the second electrical insulating heat dissipation body overlap with each other in a thickness direction of the first base plate; a third metal layer thermally connected to a side of the second electrical insulating heat dissipation body is formed at an outer side of the second base plate; and a fourth metal layer thermally connected to the second electrical insulating heat dissipation body is formed at another side of the second electrically insulating heat dissipation body;

wherein, the fourth metal layer is formed with a concave power device accommodating space, and the power device is disposed in the accommodating space.

Referring to the above-mentioned technical solution, since the power device is arranged in the accommodating space of the fourth metal layer, and both sides of the power device are each provided with the electrical insulating heat dissipation body in the thickness direction of the first base plate, both sides of the power device are protected by the rigid member during the hot pressing step of the power module manufacture. Preferably, no hot pressing pressure or merely a small hot pressing pressure is transmitted to the power device, so the damage to power device caused by the hot pressing pressure in the manufacturing process can be effectively prevented and the yield of the production of products can be greatly improved. In addition, the first electrical insulating heat dissipation body and the second electrical insulating heat dissipation body located at both sides of the power device can realize a double-sided heat dissipation of the power device, so the power module will have an excellent heat dissipation performance.

Preferably, two opposite surfaces of the power device are respectively provided with an electrode, the electrode located at one of the two opposite surfaces of the power device is electrically connected to the second metal layer. The electrode located at the other one of the two opposite surfaces of the power device is electrically connected to the fourth metal layer. The fourth metal layer is electrically connected to the second metal layer. Optionally, a plurality of electrodes of the power device are formed on a surface at the same side of the power device, and the plurality of electrodes are electrically connected to the second metal layer. Another surface of the power device opposite to the side with the plurality of electrodes is thermally connected to the fourth metal layer.

According to a specific embodiment of the present invention, the fourth metal layer is embedded in a second organic insulating medium layer for promoting the miniaturization of power modules.

In the present invention, the first electrical insulating heat dissipation body and the second electrical insulating heat dissipation body may be ceramic, such as aluminum nitride, gallium nitride, silicon carbide, silicon nitride, beryllium oxide, aluminum oxide, and the like, and preferably silicon nitride. Silicon nitride ceramics are not prone to crack even with rapid thermal-cooling cycles under large temperature differences and have an excellent thermal stability.

In the present invention, preferably, the thicknesses of the first electrical insulating heat dissipation body and the second electrical insulating heat dissipation body are respectively controlled within 0.2 mm to 0.5 mm, more preferably within 0.2 mm to 0.4 mm. The first electrical insulating heat dissipation body and the second electrical insulating heat dissipation body may have a cross-section with any shape, such as regular shapes like round, polygon, and ellipse, etc. or other irregular shapes.

In the present invention, the thickness of the fourth metal layer may be controlled within 0.2 mm to 0.5 mm, so as to form a power device accommodating space, withstand a large current (e.g., up to several hundred amps), and improve the thermal conductivity. In addition, the thicknesses of the first metal layer, the second metal layer, and the third metal layer may also be controlled within 0.2 mm to 0.5 mm, so as to carry a large current and improve the thermal conductivity thereof. Moreover, the thickness of each metal layer may be same or different.

The power module of the present invention is suitable to be packaged in a power device which has two opposite surfaces, each provided with an electrode, particularly in a power device carrying a relatively large current (e.g., up to several hundred amps). For example, the power device may be an IGBT or a MOSFET.

In order to realize the second objective mentioned above, another aspect of the present invention is to provide a method for manufacturing a power module including:

providing a first base plate, wherein the first base plate includes a first organic insulating base material and a first electrical insulating heat dissipation body embedded in the first organic insulating base material; a first metal layer thermally connected to a side of the first electrical insulating heat dissipation body is formed on a surface at a side of the first base plate; a second metal layer thermally connected to another side of the first electrical insulating heat dissipation body is formed on a surface at another side opposite to the surface side of the first base plate, and the second metal layer is patterned;

providing a heat dissipation assembly, wherein the heat dissipation assembly includes a second electrical insulating heat dissipation body, a second heat dissipation metal layer thermally connected to a side of the second electrical insulating heat dissipation body, and a fourth metal layer thermally connected to another side of the second electrical insulating heat dissipation body, and the fourth metal layer is formed with a concave power device accommodating space;

soldering a heat dissipation assembly and the power device to the second metal layer and overlapping the heat dissipation assembly and the first electrical insulating heat dissipation body with each other in a thickness direction of the first base plate, wherein the power device is placed in the power device accommodating space, and two opposite surfaces of the power device are respectively provided with electrodes;

establishing an electrical connection between an electrode at a surface of the power device and the second metal layer; preferably, establishing an electrical connection between an electrode at another surface of the power device and the fourth metal layer, and establishing an electrical connection between the fourth metal layer and the second metal layer;

sequentially layering a second organic insulating base material with a second through window and a second base material metal layer arranged on the second organic insulating base material on the first base plate, wherein the second organic insulating base material includes a prepreg and an organic insulating medium layer sequentially and alternately arranged between the first base plate and the second base material metal layer, and the heat dissipation assembly is embedded in the second through window;

performing hot pressing after the power module is layered with the second organic insulating base material;

sequentially forming a second base copper layer and a second electroplated thickened copper layer on a surface of an outer side of the second base material metal layer and the heat dissipation assembly, wherein the second base material metal layer, the second base copper layer, the second electroplated thickened copper layer, and the second heat dissipation metal layer constitute a third metal layer.

Referring to the technical solution mentioned above, since the power device is arranged in the accommodating space of the fourth metal layer and both sides of the power device are each provided with the electrical insulating heat dissipation body in the thickness direction of the first base plate, both sides of the power device are protected by the rigid member in the hot pressing step and substantially no hot pressing pressure or merely a small hot pressing pressure is transmitted to the power device, so the damage to the power device caused by the hot pressing pressure in the manufacturing process can be effectively prevented and the yield of the production of products can be greatly improved. In addition, the first electrical insulating heat dissipation body and the second electrical insulating heat dissipation body located at both sides of the power device can realize the double-sided heat dissipation of the power device, so the power module has an excellent heat dissipation performance.

In the above-mentioned technical solution, the method of providing the first base plate including:

providing a first organic insulating base material with a first through window and base material metal layers arranged on two opposite surfaces of the first organic insulating base material, wherein the first organic insulating base material includes an organic insulating medium layer and a prepreg sequentially and alternately arranged between the two base material metal layers;

placing the first electrical insulating heat dissipation body having two opposite surfaces respectively formed with a first heat dissipation metal layer in the first through window;

hot pressing the first base plate;

sequentially forming a first base copper layer and a first electroplated thickened copper layer on two opposite surfaces of the first base plate respectively; wherein, the first base material metal layer, the first heat dissipation metal layer, the first base copper layer, and the first electroplated thickened copper layer located at a surface side of the first base plate form the first metal layer, the first base material metal layer, the first heat dissipation metal layer, the first base copper layer, and the first electroplated thick copper layer located at another surface side of the first base plate form the second metal layer;

patterning the second metal layer.

In the above-mentioned technical solution, the second electrical insulating heat dissipation body may be ceramic. Preferably, the second electrical insulating heat dissipation body is a silicon nitride ceramic. Preferably, the fourth metal layer and the second heat dissipation metal layer are copper layers.

The method for providing the heat dissipation assembly including:

forming an accommodating space by performing a bending or thinning process (e.g., mechanical abrasion) on the fourth metal layer;

respectively soldering the fourth metal layer and the second heat dissipation metal layer to two opposite surfaces of the second electrical insulating heat dissipation body by using an active metal brazing process.

In the present invention, an electric conducting pattern including external electrical connection terminals may be formed on the first metal layer and/or the third metal layer. It is apparent that the first metal layer and/or the third metal layer also play a role of increasing the heat dissipation area of the module. Accordingly, the above-mentioned method includes a step of patterning the first metal layer and/or the third metal layer, and a step of establishing an electrical connection between the first metal layer and/or the third metal layer and the second metal layer.

It is apparent that in the present invention, the second metal layer may also be configured to be partially exposed to the power module to form an external electrical connection terminal of the power module. In this case, the first metal layer and the third metal layer mainly play a role of increasing the heat dissipation area of the power module.

In order to clearly describe the objectives, technical solution, and advantages of the present invention, the present invention will be described in detail with reference to the drawings and embodiments.

### BRIEF DESCRIPTION OF THE DRAWINGS

FIG. 1 is a structural schematic diagram of a preferred embodiment of the power module according to the present invention;

FIG. 2 is a structural schematic diagram of a first electrical insulating heat dissipation body portion provided according to a preferred embodiment of the power module manufacturing method of the present invention;

FIG. 3 is a structural schematic diagram of the first organic insulating base material portion provided according to a preferred embodiment of the power module manufacturing method of the present invention;

FIG. 4 is a structural schematic diagram showing that the first electrical insulating heat dissipation body portion is placed in the first organic insulating base material portion according to a preferred embodiment of the power module manufacturing method of the present invention;

FIG. 5 is a structural schematic diagram showing the hot-pressed first organic insulating base material according to a preferred embodiment of the power module manufacturing method of the present invention;

FIG. 6 is a structural schematic diagram of the first base plate according to a preferred embodiment of the power module manufacturing method of the present invention;

FIG. 7 is a structural schematic diagram of the heat dissipation assembly according to a preferred embodiment of the power module manufacturing method of the present invention;

FIG. 8 is a side view showing that the heat dissipation assembly is located at a side of the fourth metal layer according to a preferred embodiment of the power module manufacturing method of the present invention;

FIG. 9 is a schematic diagram showing that the heat dissipation assembly and the power device are soldered on the first base plate according to a preferred embodiment of the power module manufacturing method of the present invention;

FIG. 10 is a schematic diagram showing that the second organic insulating base material is hot pressed on the first base plate according to a preferred embodiment of the power module manufacturing method of the present invention;

FIG. 11 is a side view showing a side of the second organic insulating base material after the second organic insulating base material is hot-pressed according to a preferred embodiment of the power module manufacturing method of the present invention;

FIG. 12 is a schematic diagram showing that a base copper layer and an electroplated thickened copper layer are formed on a surface of the second base plate according to a preferred embodiment of the power module manufacturing method of the present invention;

FIG. 13 is a structural schematic diagram of the heat dissipation assembly portion according to another embodiment of the present invention.

### DETAILED DESCRIPTION OF THE EMBODIMENTS

FIG. 1 shows a power module according to a preferred embodiment of the present invention. As shown in FIG. 1, the power module includes a first base plate 10 and a second base plate 20 arranged in a layered structure. First base plate 10 includes first organic insulating base material 11 and first electrical insulating heat dissipation body 12 embedded in the first organic insulating base material 11. First metal layer 13 thermally connected to a side of the first electrical insulating heat dissipation body 12 is formed at the outer side of the first base plate 10. Second metal layer 14 thermally connected to another side of first electrical insulating heat dissipation body 12 is formed at the inner side of the first base plate 10. Second metal layer 14 is patterned and includes electrode pads and electrically conductive lines.

Second base plate 20 includes second organic insulating base material 21 and second electrical insulating heat dissipation body 22 embedded in the second organic insulating base material 21. First electrical insulating heat dissipation body 12 and second electrical insulating heat dissipation body 22 are configured to overlap with each other in the thickness direction of the first base plate 10. Third metal layer 23 thermally connected to a side of second electrical insulating heat dissipation body 22 is formed at the outer side of the second base plate 20. Fourth metal layer 24 thermally connected to second electrical insulating heat dissipation body 22 is formed at another side of second electrical insulating heat dissipation body 22. Fourth metal layer 24 is embedded in second organic insulating base material 21. In other embodiments of the present invention, fourth metal layer 24 may be simultaneously formed on the surfaces of second organic insulating base material 21 and second electrical insulating heat dissipation body 22.

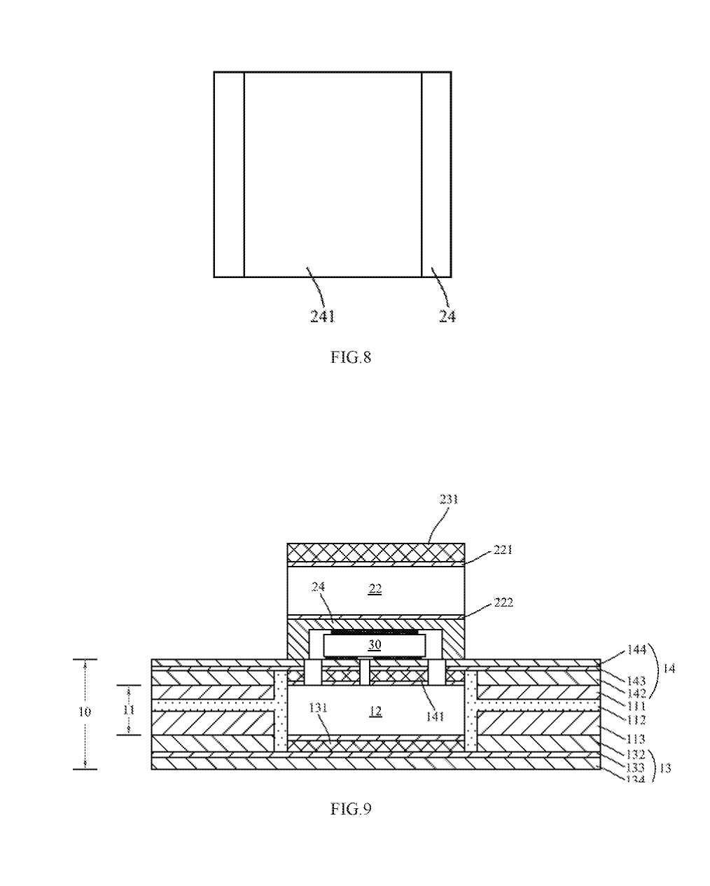

Fourth metal layer 24 is formed with concave power device accommodating space 241 (see FIG. 7 and FIG. 8). IGBT chip 30 according to an embodiment of the power device is disposed in the accommodating space 241. One surface of IGBT chip 30 is formed with a drain terminal (D-terminal), and the opposite surface is formed with a gate terminal (G-terminal) and a source terminal (S-terminal). The drain terminal of IGBT chip 30 is electrically connected to fourth metal layer 24. The gate and the source terminals are electrically connected to the corresponding electrode pad on second metal layer 14. Fourth metal layer 24 is electrically connected to second metal layer 14. It is apparent that fourth metal layer 24 can form a patterned structure including two electrode pads. In this case, the gate and the source terminals of IGBT chip 30 can be electrically connected to fourth metal layer 24, and the drain terminal can be electrically connected to second metal layer 14.

In the preferred embodiment, first electrical insulating heat dissipation body 12 and second electrical insulating heat dissipation body 22 are silicon nitride ceramics, and the thickness thereof is about 0.3 mm. The thicknesses of the first metal layer, the second metal layer, the third metal layer, and the fourth metal layer are also about 0.3 mm, respectively.

Further referring to FIG. 1, first heat dissipation metal copper layers 131 and 141 are respectively formed on the two opposite surfaces of first electrical insulating heat dissipation body 12. Second heat dissipation metal copper layers 231 and 241 are respectively formed on two opposite surfaces of second electrical insulating heat dissipation body 22. Moreover, first electrical insulating heat dissipation body 12 and first heat dissipation metal copper layers 131 and 141, as well as second electrical insulating heat dissipation body 22 and second heat dissipation metal copper layer 231 and fourth metal copper layer 241 may be connected by any means such as active metal brazing (AMB) process, silver sintering, gold sintering, etc. The thickness of the solder layer or sintered metal layer is about 20 micra. Alternatively, a metal underlayer such as titanium may be deposited on the corresponding surface of the electrical insulating heat dissipation body by a PVD (Physical Vapor Deposition) process, and then a heat dissipation metal copper layer may be formed on the metal underlayer by electroless plating and/or electroplating.

First base plate 10 includes first organic insulating base material 11. Two opposite surfaces of first organic insulating base material 11 are respectively formed with first base material metal layers 132 and 142. First base material metal layers 132 and 142 are both copper layers. First organic insulating base material 11 includes organic insulating medium layers 111 and 113 and the prepreg 112 alternately arranged between the two first base material metal layers 132 and 142, that is to say, prepreg 112 is located between organic insulating medium layers 111 and 113. It should be noted that, the prepreg is in a solid state in the finished product of power module, for the sake of simplicity, the states of the prepreg are not distinguished in the present invention, and those skilled in the art can undoubtedly determine the state change of the prepreg based on the specific descriptions of the present invention.

First base copper layers 133 and 143 are respectively formed on two opposite surfaces of first base plate 10. First electroplated thickened copper layer 134 is formed on first base copper layer 133. First electroplated thickened copper layer 144 is formed on first base copper layer 143. First heat dissipation metal layer 131, first base material metal layer 132, first base copper layer 133, and first electroplated thickened copper layer 134 located at the outer surface side of the first base plate 10 constitute first metal layer 13. First heat dissipation metal layer 141, first base material metal layer 142, first base copper layer 143, and first electroplated thickened copper layer 144 located at the inner surface side of the first base plate 10 constitute second metal layer 14.

Second base plate 20 includes second organic insulating base material 21 and second base material metal layer 232 located at the outer side of second organic insulating base material 21. Similarly, second base material metal layer 232 is also a copper layer. Second organic insulating base material 21 includes prepregs 211 and 213, and organic insulating medium layers 212 and 214. Prepregs 211 and 213 and organic insulating medium layers 212 and 214 are alternately arranged between first base plate 10 and second base material metal layer 232. It is apparent that the number of the layers of the prepregs and the organic insulating medium layers in first organic insulating base material 11 and second organic insulating base material 21 may be set as needed.

Second base copper layer 233 is formed on the outer surface of second base plate 20. Second electroplated thickened copper layer 234 is formed on second base copper layer 233. Second heat dissipation metal layer 231, second base material metal layer 232, second base copper layer 233, and second electroplated thickened copper layer 234 constitute third metal layer 23.

It is apparent that, patterned electrically conductive line layers may be formed in first organic insulating base material 11 and second organic insulating base material 21 in the present invention although not shown in FIG. 1.

Hereinafter, a preferred embodiment of the manufacturing method of the power module shown in FIG. 1 will be further described. With the descriptions, the structure of the power module shown in FIG. 1 will be more clearly understood.

The manufacturing method of the power module according to a preferred embodiment of the present invention includes the steps of providing first base plate 10. First base plate 10 includes first organic insulating base material 11 and first electrical insulating heat dissipation body 12 embedded in first organic insulating base material 11. First metal layer 13 thermally connected to a side of first electrical insulating heat dissipation body 12 is formed at a surface side of first base plate 10. Second metal layer 14 thermally connected to another side of first electrical insulating heat dissipation body 12 is formed at another opposite surface side of the first base plate 10, and second metal layer 14 is patterned.

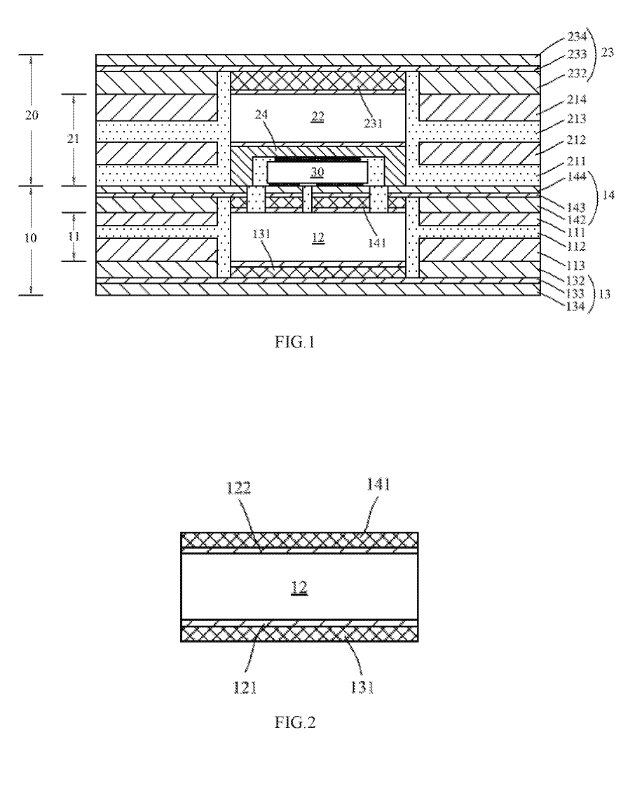

Specifically, referring to FIG. 2, the step of providing first base plate 10 includes respectively soldering first heat dissipation metal layers 131 and 141 on the two opposite surfaces of first electrical insulating heat dissipation body 12 by using an active metal brazing process. First electrical insulating heat dissipation body 12 is made of silicon nitride and has a thickness of about 0.3 mm. Solder layer 121 is arranged between first heat dissipation metal layer 131 and first electrical insulating heat dissipation body 12. Solder layer 122 is arranged between first heat dissipation metal layer 141 and first electrical insulating heat dissipation body 12. The thickness of both of first solder layer 121 and second solder layer 122 is about 20 micra.

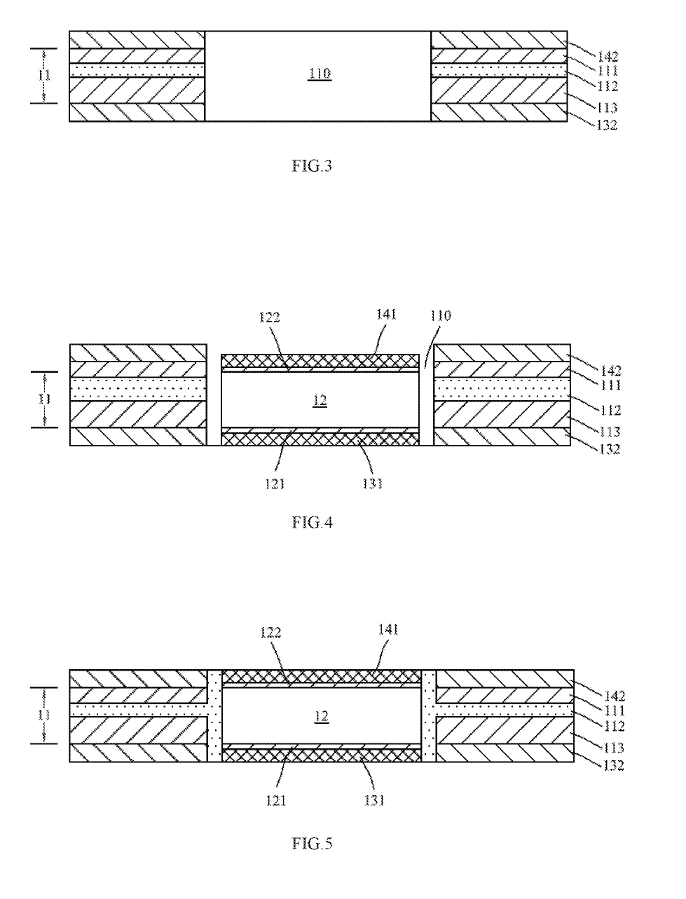

As shown in FIG. 3, the manufacture of first base plate 10 includes providing first organic insulating base material 11 with first through window 110 and first base material metal layers 132 and 142 arranged on two opposite surfaces of first organic insulating base material 11. First organic insulating base material 11 includes layered organic insulating medium layers 111 and 113 and prepreg 112 arranged between organic insulating medium layers 111 and 113. Organic insulating medium layer 111 and base material metal layer 142 are provided together in the form of copper clad laminate. Similarly, organic insulating medium layer 113 and base material metal layer 132 are also provided together in the form of copper clad laminate. In the present invention, the organic insulating medium layer may be organic insulating mediums suitable for insulating base material of circuit board such as FR4 or BT, and the organic insulating medium may be filled with inorganic fillers such as ceramic particles to enhance the thermal conductivity.

As shown in FIG. 4, the manufacture of first base plate 10 includes the step of placing first electrical insulating heat dissipation body 12 having two opposite surfaces respectively formed with first heat dissipation metal layers 131 and 141 into first through window 110.

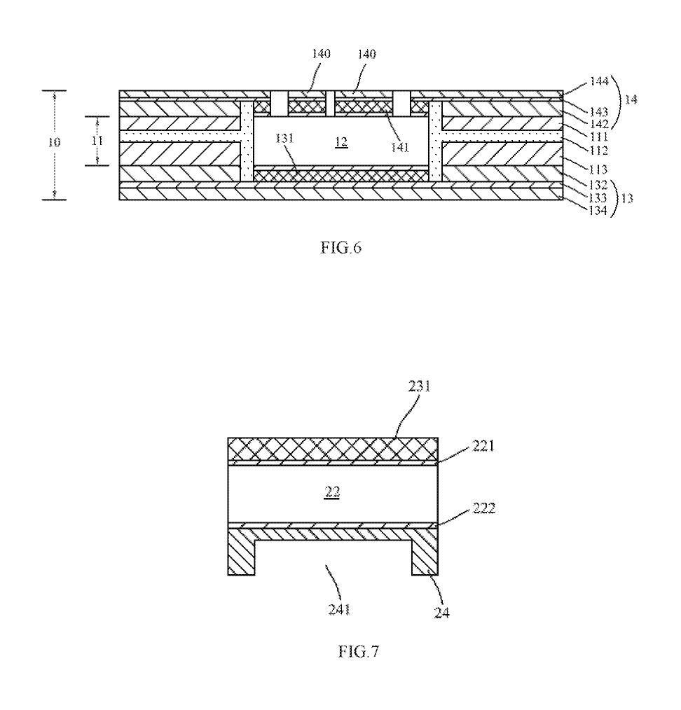

The manufacture of first base plate 10 further includes the step of hot pressing first base plate 10. During the hot pressing, prepreg 112 flows to fill the gaps in the window 110 and becomes solid to connect first organic insulating base material 11 and first electrical insulating heat dissipation body 12. When the hot pressing is completed, as shown in FIG. 5, the two opposite surfaces of first base plate 10 are flat surfaces. The possibly involved step of removing (e.g., mechanical abrasion) the resin flowing to the surfaces of first heat dissipation metal layers 131 and 141 and first base material metal layers 132 and 142 during the hot pressing process is controlled according to the hot pressing process.

The manufacture of first base plate 10 further includes the steps of forming first base copper layers 133 and 143 by electroless plating, and forming first electroplated thickened copper layers 134 and 144 by electroplating process on the two opposite surfaces of first base plate 10, respectively and sequentially. First heat dissipation metal layer 131, first base material metal layer 132, first base copper layer 133, and first electroplated thickened copper layer 134 located at one surface side of first base plate 10 constitute first metal layer 13 with a thickness of about 0.3 mm. First heat dissipation metal layer 141, first base material metal layer 142, first base copper layer 143, and first electroplated thickened copper layer 144 located at the other surface side of first base plate 10 constitute second metal layer 14 with a thickness of about 0.3 mm.

The manufacture of first base plate 10 further includes the step of patterning second metal layer 14 (here refers that the process of patterning solder layer 122 is also involved) to form an electrically conductive pattern including a plurality of electrode pads 140 located on first electrical insulating heat dissipation body 12. The obtained first base plate 10 has a structure as shown in FIG. 6.

The manufacturing method of the power module according to a preferred embodiment of the present invention includes the step of providing a heat dissipation assembly. FIG. 7 is a structural schematic diagram of the heat dissipation assembly, and FIG. 8 is a side view showing a side of fourth metal layer 24. Referring to FIG. 7 and FIG. 8, the heat dissipation assembly includes second electrical insulating heat dissipation body 22, second heat dissipation metal layer 231 thermally connected to a side of second electrical insulating heat dissipation body 22, and fourth metal layer 24 thermally connected to another side of second electrical insulating heat dissipation body 22. Fourth metal layer 24 is formed with a concave power device accommodating space 241. Fourth metal layer 24 is subjected to a thinning treatment (for example, mechanical cutting) to form accommodating space 241.

The second electrical insulating heat dissipation body 22 is made of silicon nitride and has a thickness of about 0.3 mm. Solder layer 221 is arranged between second heat dissipation metal layer 231 and second electrical insulating heat dissipation body 22. Solder layer 222 is arranged between fourth metal layer 24 and second electrical insulating heat dissipation body 22. The thickness of solder layer 221 and solder layer 222 is about 20 micra, and the maximum thickness of fourth metal layer 24 is about 0.3 mm.

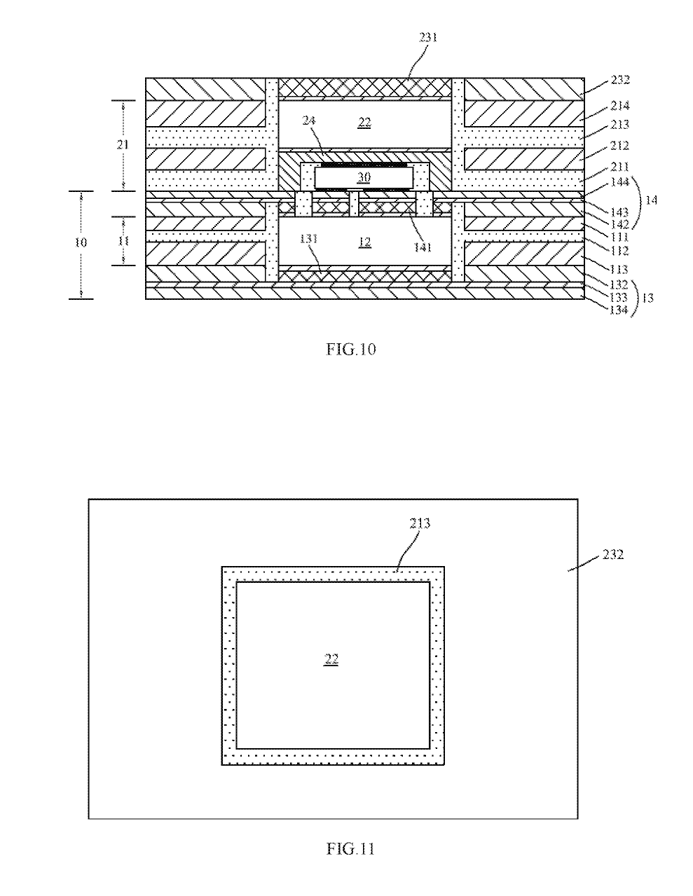

Referring to FIG. 9, the manufacturing method of power module according to a preferred embodiment of the present invention includes the step of soldering the heat dissipation assembly and IGBT chip 30 considered as an embodiment of the power device to second metal layer 14. The heat dissipation assembly overlap with first electrical insulating heat dissipation body 12 in the thickness direction of first base plate 10. IGBT chip 30 is placed in power device accommodating space 241. One surface of IGBT chip 30 is formed with a drain terminal, and the other opposite surface is formed with a gate terminal and a source terminal. An electrical connection is established between the drain terminal of IGBT chip 30 and fourth metal layer 24 by soldering, an electrical connection is established between the gate and source terminal of IGBT chip 30 and the corresponding electrode pads 140 on second metal layer 14, similarly, an electrical connection is established between fourth metal layer 24 and second metal layer 14.

Referring to FIG. 10 and FIG. 11, the manufacturing method of power module according to a preferred embodiment of the present invention includes the step of sequentially layering second organic insulating base material 21 with the second through window and second base material metal layer 232 on first base plate 10. The heat dissipation assembly is embedded in the second through window. Second organic insulating base material 21 includes prepregs 211 and 213 and organic insulating medium layers 212 and 214 sequentially and alternately arranged between first base plate 10 and second base material metal layer 232. Second base material metal layer 232 and organic insulating medium layer 214 are provided in the form of copper clad laminate.

Similarly, referring to FIG. 10 and FIG. 11, the manufacturing method of power module according to a preferred embodiment of the present invention includes the step of hot pressing the power module after second organic insulating base material 21 is layered. During the hot pressing, prepregs 211 and 213 flow to fill the gaps in the second through window and accommodating space 241, and become solid to connect first base plate 10 and second base plate 20. Moreover, the possibly involved step of removing (e.g., mechanical abrasion) the resin flowing to the surfaces of second heat dissipation metal copper layer 231 and second base material metal layer 232 during the hot pressing process is controlled according to the hot pressing process.

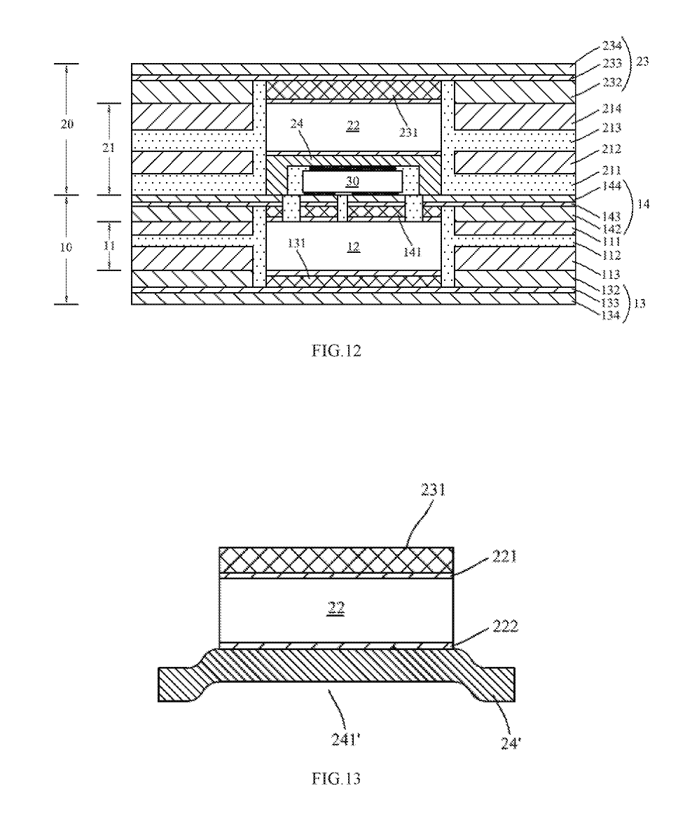

Referring to FIG. 12, the manufacturing method of power module according to a preferred embodiment of the present invention further includes the step of sequentially forming second base copper layer 233 and second electroplated thickened copper layer 234 on the surfaces of the outer side of second base material metal layer 232 and the heat dissipation assembly (i.e., the surface of the outer side of second heat dissipation metal layer 231). Second heat dissipation metal layer 231, second base material metal layer 232, second base copper layer 233, second electroplated thickened copper layer 234 constitute third metal layer 23 with a thickness of about 0.3 mm.

In other embodiments of the present invention, an electrically conductive pattern including external electrical connection terminals may be formed on first metal layer 13 and/or third metal layer 23. Accordingly, in this case, the method of the present invention further includes the steps of patterning first metal layer 13 and/or third metal layer 23, and establishing an electrical connection between first metal layer 13 and/or third metal layer 23 and second metal layer 14.

It is apparent that in other embodiments of the present invention, a plurality of electrodes of the power device may be formed on the surface at the same side, and the plurality of electrodes are electrically connected to second metal layer 14. The surface of the other side opposite to the side of the plurality of electrodes of the power device is thermally connected to fourth metal layer 24.

FIG. 13 shows a structural schematic diagram of the heat dissipation assembly according to other embodiments of the present invention. Referring to FIG. 13, the difference between this heat dissipation assembly and the heat dissipation assembly shown in FIG. 7 and FIG. 8 is that power device accommodating space 241′ is formed by bending fourth metal layer 24′ (for example, the bending process is performed by using bending molds).

Although the present invention has been described above according to the preferred embodiments, it should be understood that any equivalent improvement derived from the present invention by those skilled in the art without departing from the scope of the invention shall fall within the scope of the present invention.

1. A power module with a built-in power device and double-sided heat dissipation, comprising:
a first base plate, wherein the first base plate comprises a first organic insulating base material and a first electrical insulating heat dissipation body embedded in the first organic insulating base material, a first metal layer thermally connected to a first side of the first electrical insulating heat dissipation body is formed at an outer side of the first base plate, a second metal layer thermally connected to a second side of the first electrical insulating heat dissipation body is formed at an inner side of the first base plate, and the second metal layer is patterned; and
a second base plate, wherein the second base plate comprises a second organic insulating base material and a second electrical insulating heat dissipation body embedded in the second organic insulating base material, the first electrical insulating heat dissipation body and the second electrical insulating heat dissipation body overlap with each other in a thickness direction of the first base plate, a third metal layer thermally connected to a first side of the second electrical insulating heat dissipation body is formed at an outer side of the second base plate, and a second side of the second electrical insulating heat dissipation body is formed with a fourth metal layer thermally connected to the second electrical insulating heat dissipation body; and
wherein the fourth metal layer is formed with a concave power device accommodating space, and the built-in power device is arranged in the concave power device accommodating space, and
wherein the second organic insulating base material comprises prepregs and organic insulating medium layers sequentially and alternately arranged.

2. The power module with the built-in power device and double-sided heat dissipation according to claim 1, wherein the fourth metal layer is embedded in the second organic insulating base material.

3. The power module with the built-in power device and double-sided heat dissipation according to claim 1, wherein the first electrical insulating heat dissipation body and the second electrical insulating heat dissipation body are ceramic.

4. The power module with the built-in power device and double-sided heat dissipation according to claim 3, wherein the ceramic is one item selected from the group consisting of silicon nitride, aluminum nitride, and aluminum oxide ceramic.

5. The power module with the built-in power device and double-sided heat dissipation according to claim 1, wherein the power device is one item selected from the group consisting of thyristor, insulated gate bipolar transistor, metal-oxide semiconductor field effect transistor, gate turn-off thyristor, giant transistor, and bipolar junction transistor.

6. The power module with the built-in power device and double-sided heat dissipation according to claim 1, wherein a thickness of the first electrical insulating heat dissipation body and the second electrical insulating heat dissipation body is respectively controlled within 0.2 mm to 0.5 mm; and
a thickness of the first metal layer, the second metal layer, the third metal layer, and the fourth metal layer is respectively controlled within 0.2 mm to 0.5 mm.

7. The power module with the built-in power device and double-sided heat dissipation according to claim 1, wherein a first surface of the power device is provided with a first electrode; and a second surface of the power device is provided with a second electrode; the first surface is opposite to the second surface;
the first electrode at the first surface of the power device is electrically connected to the second metal layer;
the second electrode at the second surface of the power device is electrically connected to the fourth metal layer; and the fourth metal layer is electrically connected to the second metal layer.

8. A manufacturing method for a power module, comprising:
providing a first base plate, wherein the first base plate comprises a first organic insulating base material and a first electrical insulating heat dissipation body embedded in the first organic insulating base material, a first metal layer thermally connected to a first side of the first electrical insulating heat dissipation body is formed at a first surface side of the first base plate, a second metal layer thermally connected to a second side of the first electrical insulating heat dissipation body is formed at a second surface side opposite to the first surface side of the first base plate, and the second metal layer is patterned;
providing a heat dissipation assembly, wherein the heat dissipation assembly comprises a second electrical insulating heat dissipation body, a second heat dissipation metal layer thermally connected to a first side of the second electrical insulating heat dissipation body, and a fourth metal layer thermally connected to a second side of the second electrical insulating heat dissipation body, and the fourth metal layer is formed with a concave power device accommodating space;
soldering the heat dissipation assembly and a power device to the second metal layer and overlapping the heat dissipation assembly and the first electrical insulating heat dissipation body with each other in a thickness direction of the first base plate, wherein the power device is placed in the concave power device accommodating space, and two opposite surfaces of the power device are respectively provided with a first electrode and a second electrode;
establishing a first electrical connection between the first electrode at a first surface of the power device and the second metal layer;
establishing a second electrical connection between the second electrode at a second surface of the power device and the fourth metal layer;
establishing a third electrical connection between the fourth metal layer and the second metal layer;
sequentially layering a second organic insulating base material with a second through window and a second base material metal layer disposed on the second organic insulating base material on the first base plate, wherein the second organic insulating base material comprises a prepreg and an organic insulating medium layer sequentially and alternately arranged between the first base plate and the second base material metal layer, the heat dissipation assembly is embedded in the second through window;
performing hot pressing after the power module is layered with the second organic insulating base material;
sequentially forming a second base copper layer and a second electroplated thickened copper layer on a surface of an outer side of the second base material metal layer and the heat dissipation assembly, wherein the second base material metal layer, the second base copper layer, the second electroplated thickened copper layer, and the second heat dissipation metal layer constitute a third metal layer; and
wherein a second base plate comprises the second organic insulating base material and the second electrical insulating heat dissipation body embedded in the second organic insulating base material, the first electrical insulating heat dissipation body and the second electrical insulating heat dissipation body overlap with each other in the thickness direction of the first base plate, the third metal layer thermally connected to the first side of the second electrical insulating heat dissipation body is formed at an outer side of the second base plate.

9. The manufacturing method for the power module according to claim 8, wherein the step of providing the first base plate comprises:
providing the first organic insulating base material with a first through window and first base material metal layers arranged on two opposite surfaces of the first organic insulating base material, wherein the first organic insulating base material comprises an organic insulating medium layer and a prepreg sequentially and alternately arranged between the two first base material metal layers;
placing the first electrical insulating heat dissipation body with two opposite surfaces respectively formed with the first heat dissipation metal layer in the first through window;
performing hot pressing on the first base plate;
sequentially forming a first base copper layer and a first electroplated thickened copper layer on two opposite surfaces of the first base plate, respectively, wherein, the first base material metal layer, the first heat dissipation metal layer, the first base copper layer, and the first electroplated thickened copper layer located at a first surface side of the first base plate form the first metal layer, the first base material metal layer, the first heat dissipation metal layer, the first base copper layer, and the first electroplated thickened copper layer located at a second surface side of the first base plate form the second metal layer; and
patterning the second metal layer.

10. The manufacturing method for the power module according to claim 8, wherein the second electrical insulating heat dissipation body is a ceramic; the fourth metal layer and the second heat dissipation metal layer are copper layers; and the method of providing the heat dissipation assembly comprises forming an accommodating space by a bending or thinning process performed on the fourth metal layer; respectively soldering the fourth metal layer and the second metal layer to two opposite surfaces of the second electrical insulating heat dissipation body by using an active metal brazing process.

11. The manufacturing method for the power module according to claim 8, further comprising
patterning the first metal layer and/or the third metal layer; and
establishing a fourth electrical connection between the first metal layer and/or the third metal layer and the second metal layer.

12. The power module with the built-in power device and double-sided heat dissipation according to claim 1, wherein the first metal layer is exposed to the first organic insulating base material, and the third metal layer is exposed to the second organic insulating base material.

13. The power module with the built-in power device and double-sided heat dissipation according to claim 12, wherein
the first metal layer includes a first base material metal layer formed on an outer surface of the first organic insulating base material, a first heat dissipation metal layer formed on the first side surface of the first electrical insulating heat dissipation body, and a first base copper layer and a first electroplated thickened copper layer on the first base material metal layer and the first heat dissipation metal layer; and
the third metal layer includes a second base material metal layer formed on an outer surface of the second organic insulating base material, a second heat dissipation metal layer formed on a first side surface of the second electrical insulating heat dissipation body, and a second base copper layer and a second electroplated thickened copper layer formed on the second base material metal layer and the second heat dissipation metal layer.
